(19) United States
(12) Patent Application Publication
(10) Pub. No.: US 2011/0254134 A1
(43) Pub. Date: Oct. 20, 2011

(54) Method of Group III Metal - Nitride Material Growth Using Metal Organic Vapor Phase Epitaxy

(76) Inventors: Theeradetch Detchprohm, Niskayuna, NY (US); Mingwei Zhu, Santa Clara, CA (US); Christian Wetzel, Troy, NY (US)

(21) Appl. No.: 13/087,614

(22) Filed: Apr. 15, 2011

Related U.S. Application Data
(60) Provisional application No. 61/325,609, filed on Apr. 19, 2010.

(51) Int. Cl. H01L 29/20; B32B 38/10; C30B 25/02

(52) U.S. Cl. 257/615; 117/104; 156/701; 257/E29.089

(57) ABSTRACT

The non-polar or semi-polar Nitride film is grown using Metal Organic Vapor Phase Epitaxy over a substrate. The in-situ grown seed layer comprising Magnesium and Nitrogen is deposited prior to the Nitride film growth. The said seed layer enhances the crystal growth of the Nitride material and makes it suitable for electronics and optoelectronics applications. The use of non-polar and/or semi-polar epitaxial films of the Nitride materials allows avoiding the unwanted effects related to polarization fields and associated interface and surface charges, thus significantly improving the semiconductor device performance and efficiency. In addition, the said seed layer is also easily destroyable by physical or chemical stress, including the ability to dissolve in water or acid, which makes the substrate removal process available and easy. The substrate removal provides the possibility to achieve exceptional thermal conductivity and application flexibility, such as additional contact formation, electromagnetic radiation extraction, packaging or other purposes suggested or discovered by the skilled artisan.

### CROSS-REFERENCE TO RELATED APPLICATION

This application claims the benefit of Provisional Patent Application Ser. No. 61/325,609, filed on Apr. 19, 2010 by present inventors.

### FEDERALLY SPONSORED RESEARCH

Not Applicable

### SEQUENCE LISTING OR PROGRAM

Not Applicable

### FIELD OF THE DISCLOSURE

Aspects of the invention relate to the compound semiconductor material growth technique over a substrate, and in particular, to the Metal Organic Vapor Phase Epitaxy (MOVPE) of Boron Nitride, Aluminum Nitride, Gallium Nitride, Indium Nitride, and their combinative compounds in the crystalline direction, other than Ga-polar <0001> direction, over commercially available, cost-effective large area substrates.

### BACKGROUND OF THE DISCLOSURE

Gallium Nitride and related alloys (Indium Nitride, Aluminum Nitride and their ternary and quaternary alloys, referred here as Nitride materials) are emerging materials for many applications in semiconductor industry, for electronics and especially optoelectronics applications. Their practical usefulness is, in particular, well established for production of visible and ultraviolet Light Emitting Diodes and Laser Diodes. These said materials are typically grown using epitaxial growth techniques such as Metal Organic Vapor Phase Epitaxy (MOVPE), Molecular Beam Epitaxy (MBE), and Hydride Vapor Phase Epitaxy (HVPE).

The most stable crystalline structure for the Nitride materials is the hexagonal wurtzite structure. It consists of the layers of Nitrogen and Metal (Boron, Indium, Gallium or Aluminum) atoms that are called c-planes and have hexagonal planar symmetry. The direction perpendicular to the c-planes is called c-axis. The growth direction of the epitaxial film is called (Metal)-polar (for example, Gallium-polar, Ga-polar) if the newly formed surface comprises the c-plane consisting of Metal (Gallium, in the prior example) atoms. For the (Metal)-polar film, the spontaneous polarization vector points perpendicular to the film surface, in the direction opposite to the growth direction. The growth direction of the epitaxial film is called Nitrogen-polar (N-polar) if the newly formed surface comprises the c-plane consisting of the Nitrogen atoms. For the N-polar film, the spontaneous polarization vector points perpendicular to the film surface, in the direction from surface to the ambient, outwards the substrate (in the direction of growth). Accordingly, the newly formed surface is called Metal-face or Nitrogen-face, respectively. Conventionally, the positive direction of the c-axis corresponds to the growth direction of the (Metal)-polar film. Therefore, for the Nitride materials the c-axis component of the spontaneous polarization is always negative.

The growth direction of the epitaxial film is called non-polar, and the corresponding newly formed surface is called non-polar face, if the spontaneous polarization field has no component in the said growth direction. The polar and non-polar growth directions are perpendicular to each other in terms of crystalline orientation.

It is possible by means of the growth, or by using selective directional etch, or by using other surface preparation methods, to obtain plain surfaces of Nitride material that are neither Metal-polar, nor N-polar nor non-polar. Such planes and corresponding crystallographic directions are called semi-polar. With respect to the common notation system based on Miller-Bravais indices of symmetry, the Metal-polar and N-polar planes are {0001} (the family of crystallographic planes equivalent by symmetry to the (0001) plane); non-polar planes include {11-20}, or a-planes, and {1-100}, or m-planes. The most commonly employed semi-polar planes include, but are not limited to, the {11-22}, {10-11} and {10-13} families. Here and throughout the present description, for distinctiveness, we assume that the Miller-Bravais indices are given in reduced form, so that their greatest common divisor is 1. [06] Yet the most limiting factor for the nitride materials' practical usage is their high cost associated with the material fabrication itself. To date, successful implementation of only one modification of the epitaxially grown Ga-polar, films, with crystalline orientation along the c-axis, is intensively discussed in the available literature. At the same time, a polar growth orientation significantly limits the performance of semiconductor devices fabricated using such films. In optoelectronics, in particular, the presence of high polarization fields leads to the effect known as Quantum Confined Stark Effect (QCSE) which causes spatial separation of electrons and holes inside a quantum well and therefore may reduce the efficiency of the light generation.

Although non-polar and semi-polar faces are usually considered as preferable for the optoelectronic applications, just preparing the corresponding crystal surfaces by, for example, bulk crystal polishing does not yet provide the material suitable for the device fabrication. It is essential also for the successful device fabrication that the said non-polar or semi-polar plane corresponds to the actual growth direction. Only in this case, smooth and uniform layers of material with lower band gap (quantum wells) or larger band gap (quantum walls) can be inserted during the growth into the active regions of fabricated devices. The quality, uniformity and repeatability of these layers are the key factors determining the performance and efficiency of the resulting device. The quality of the quantum well layers is, in turn, in direct dependence of the quality of the base grown material.

Since the Nitride materials grown in the semi-polar direction still have some residual polarization in the direction of the growth, it is important to determine and control the direction of the polarization field with respect to the surface of the film. If the spontaneous polarization vector has a component perpendicular to the film surface, and the said component's direction is opposite to the growth direction, then the film is referred to as (Metal)-semi-polar (for example, Ga-semi-polar) face. Accordingly, if the spontaneous polarization vector has a component perpendicular to the film surface, and the said component's direction is the same as the growth direction, then the film is referred to as N-semi-polar face. The top surface of the (Metal)-semi-polar face is formed by metal atoms, while the top surface of the N-semi-polar face is formed by Nitrogen atoms. For simplicity, we refer to both (Metal)-polar and (Metal)-semi-polar face as Metal-face (for example, Ga-face), and to both N-polar face and N-semi-polar face as N-face.

When one Nitride film is deposited on top of the other, their interface carries the charge equal to the discontinuity of the total polarization field at the interface, including spontaneous and piezoelectric components of polarization vector due to the strain induced by lattice mismatch between the materials. The combination of spontaneous and piezoelectric polarization discontinuity at the interface between two semi-polar layers of the Nitride material may result in significant reduction or even cancellation of the polarization fields and associated charges at the said interface. This occurs if spontaneous and piezoelectric polarizations have opposite directions. While the direction of the spontaneous polarization is determined by the face type of the film grown, the direction of the piezoelectric polarization is given by the type of the strain induced in both films, tensile or compressive. It may also depend on other parameters such as the lattice temperature. The type of strain depends on the crystal lattice mismatch and is opposite, for example, between AlGaN compounds and GaInN compounds grown on the relaxed GaN buffer.

Different surface polarities, or faces, of the Nitride material film, also behave differently during the growth of the compounds. It is speculated, for example, that the incorporation of Indium into the GaInN layer occurs more effectively during the growth on N-face, due to stronger bonds formed between upcoming Indium atoms and the growth surface (S. Keller, N. A. Fichtenbaum, M. Furukawa, J. S. Speck, S. P. DenBaars, and U. K. Mishra, “Growth and characterization of N-polar InGaN/GaN multiquantum wells”, Appl. Phys. Letters, V. 90, Issue 19, pp. 191908-191910). Therefore, the skilled artisan, while designing the Nitride material based device, must be able to select the face type of the material for each particular layer structure in order to properly control and optimize the charges at the most important interfaces. Thus, it is essential for the device design and optimization to control the polarity of the grown film, or in other words, its face type.

In the past, the growth along semi-polar directions was successfully demonstrated by several research groups using two distinct techniques. In one technique, the growth is performed over the corresponding surface of the native substrate, obtained by cleaving or chemical-mechanical polishing, using MOVPE or HVPE. Here, by the native substrate we understand the substrate comprising the crystal(s) of Nitride material. The variations of this technique include special surface treatments prior to growth, such as aggressive etch, and/or growth of one or more nucleation layers, transitional layers and defect stopping layers comprising the Nitride materials of different composition.

The limitation of this technique is the necessity of having bulk native substrate to prepare the initial layer stable enough to support the process of growth. The said bulk substrate has to be obtained by some other method, which is often challenging and very expensive. Until now, the availability of such bulk substrates is limited in quality and size, making this method unsuitable for the mass production. Another important limitation is the uncontrolled growth of so-called twin crystals—two separate crystals that share some of the same crystal lattice points in a symmetrical manner. As a result of twinning, instead of the single crystal growth, the polycrystalline film is grown with twin boundaries and stacking faults, which behave as defects limiting the performance of the devices fabricated using such films.

Yet another technique is based on special treatment and preparation of the c-plane surface of the native substrate, not necessarily bulk, so that the growth over such a surface occurs, among other directions, in one or more of the semi-polar directions. The material obtained using such technique is also highly non-uniform and suffers from the presence of grain boundaries, twinning, stacking faults, so that the technique produces small, randomly distributed useful portions of the material, which again limits the availability of this method for the mass production of high quality devices.

Both prior art techniques discussed above produce the same face type of the Nitride material film, namely the Ga-face.

Recently the possibility of Nitride material growth in non-polar and semi-polar direction was discovered using a specific plane of sapphire substrate, namely the m-plane. However, the obtained films are of extremely low quality, comprising polycrystalline material, twin boundaries and dislocations/stacking faults in unpredictable manner. It was suggested to improve the crystal quality of such layers by introducing the interlayers of Scandium Nitride (M. A. Moram, C. F. Johnston, M. J. Kappers, C. J. Humphreys, “Defect reduction in nonpolar and semipolar GaN using scandium nitride interlayers”, Journal of Crystal Growth, V. 311, pp. 3239-3242, 2009). The disadvantages of this method include the impossibility to cure the grain boundaries between the crystals and the absence of an MOVPE deposition method for Scandium Nitride, so that it requires the sample removal from the reactor, deposition of the Scandium metal layer by some other technique (for example, Magnetron Sputtering), followed by nitridation of the said Scandium layer in the growth reactor, which represents additional technological step substantially increasing the cost of the device fabrication. It has to be mentioned also that Scandium is quite rare element, and its availability for the technology is currently limited.

The development of the method of growing non-polar and/or semi-polar faced Nitride material over large and (preferably) cheap substrates that produces the films with N-face is therefore extremely important for the fabrication and production of high quality and affordable price Nitride material based optoelectronic devices emitting light in both visible and ultraviolet spectral ranges. Additional requirement that not necessarily but preferably have to be addressed is the possibility of robust substrate removal for both electrical (contact) accessibility of the bottom layers of the grown film and enhanced light extraction in case of optoelectronics applications.

### SUMMARY OF THE INVENTION

Aspects of the invention are directed to the Nitride materials' (Boron Nitride's (BN), Aluminum Nitride's (AlN), Gallium Nitride's (GaN), Indium Nitride's (InN), and their alloys') crystal growth over a substrate using MOVPE technique, in crystal orientation other than polar (c-axis) direction. It is understood that the same growth technique may be referred to in different terms, such as, for example, Metal-Organic Chemical Vapor Deposition (MOCVD), or any other terms known to any one skilled in the art to refer to essentially the same deposition method.

An objective of the present invention is to provide a method for the crystal growth of a compound semiconductor material, in particular BN, AlN, GaN, InN and their compounds, that produces crystalline films with the surface crystallographic orientation corresponding to a semi-polar or non-polar plane, or polar N-face plane, to improve the current technology in aspects of—including, but not limited to—Light Emitting Diode performance and efficiency improvement, Laser Diode performance and efficiency improvement, and Photovoltaic Device performance and efficiency improvement, as well as reliability enhancement, cost reduction and advanced options for the new device design concepts.

According to the present invention this can be achieved by applying the MOVPE technique of Nitride semiconductor's semi-polar film growth to a substrate, including but not limited to sapphire substrate with top m-plane surface, or any other suitable substrate discoverable by skilled artisan. More specifically, the said substrate is placed into the MOVPE reactor in Hydrogen ambient, where it is heated up uniformly to the deposition temperature in the range 500-1500 degrees Celsius, or limited by the melting point of the said substrate. After the desired temperature is reached uniformly over the said substrate, a thin layer of a seed material is deposited by activation of the material sources of Magnesium and Nitrogen (for example which does not limit the scope of the present disclosure, Bis(cyclopentadienyl)magnesium (usually referred to as Cp₂Mg) and Ammonia). The said seed material is known from prior art to assist in Nitride material growth in polar {0001} direction, and in a certain level of the defect reduction thereof. Since Magnesium is commonly used as a dopant to induce the p-type conductivity in the Nitride materials during the MOVPE growth, its presence does not require any material sources other than the sources naturally present in the MOVPE process.

In another embodiment of the invention, the uniform growth of the Nitride material film over the substrate with pre-deposited said seed layer along the <11-22> direction is continued, followed by deposition of another Nitride material or alloy layer or layers having same crystallographic orientation, if desired, in purpose of creating a heterojunction or a system of heterojunctions suitable for semiconductor device fabrication.

In yet another embodiment of the present invention, the Nitride material and/or heterostructure of the Nitride materials over the substrate with pre-deposited said seed layer, having semi-polar surface with Nitrogen face type is subject to the substrate removal utilizing the property of the said seed material to be easily destroyed by physical or chemical stress or processes.

In a first aspect of the present invention, seed layer comprising Magnesium and Nitrogen, of the thickness of 0.1 nm to 0.1 mm, is formed over the substrate using a MOVPE technique with Cp₂Mg and Ammonia sources active.

In a second aspect of the present invention, the semi-polar single crystal growth of a Nitride material or Nitride material based heterostructure is performed in semi-polar direction using MOVPE technique.

In a third aspect of the present invention, the said Nitride material and/or heterostructure is controllably grown in pre-selected, Nitrogen-face or Metal-face polarity.

In a fourth aspect of the present invention, the said seed layer can be easily destroyed by physical or chemical stress or processes, leading to the substrate removal from the as-grown film, leaving a free-standing epitaxial film suitable for e.g. wafer-bonding.

In a fifth aspect of the present invention, the said seed layer can be easily destroyed by physical or chemical stress or processes, leading to a substrate removal from a single device die, for packaging advances, light extraction improvement, thermal management improvement and/or electrical access to the layers grown underneath the epitaxial structure.

### BRIEF DESCRIPTION OF THE DRAWINGS

These and other features of the present invention will be more readily understood from the following brief description of the various aspects of the invention taken in conjunction with the accompanying drawings. It is noted that the drawings and description are only given in exemplary manner and cannot limit the scope of the present invention.

FIG. 1 depicts a schematic layer structure for the material grown using present invention.

FIG. 2 presents the X-Ray Diffraction data confirming the growth of semi-polar GaN film using present invention.

FIG. 3 presents the X-Ray Diffraction data demonstrating the quality of the semi-polar GaN film grown using present invention.

FIG. 4 shows a lower-resolution Differential Interference Contrast (DIC) Microscopy image of the surface of semi-polar GaN deposited using conventional MOVPE technique over the m-plane sapphire substrate.

FIG. 5 shows yet another lower-resolution DIC Microscopy image of the surface of semi-polar GaN deposited using conventional MOVPE technique over the m-plane sapphire substrate.

FIG. 6 shows a lower-resolution DIC Microscopy image of the surface of semi-polar GaN deposited using the technique of the present invention over the m-plane sapphire substrate.

FIG. 7 presents the Transmission Electron Microscopy (TEM) high resolution image of the Substrate/Seed Layer/GaN layer deposited using the technique of the present invention.

FIG. 8 provides the insight to the face type validation of the grown GaN film by the method of Convergent Beam Electron Diffraction (CBED).

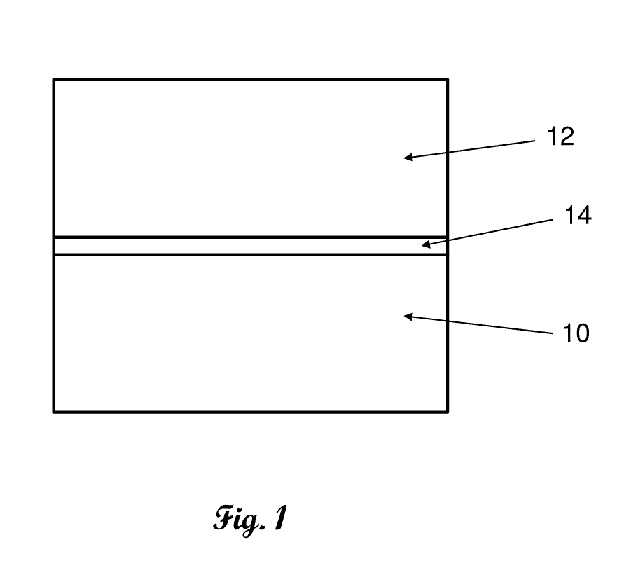

It is noted that FIG. 1 of the drawings accompanying the invention description is not to scale. The drawings are intended to depict only typical aspects of the invention, and therefore should not be considered as limiting the scope of the invention.

### DETAILED DESCRIPTION

FIG. 1 depicts schematically the layer structure of the epitaxial layer 12 grown on a substrate 10 utilizing the seed layer 14 deposition for proper initiation and quality improvement of the layer 12. The seed layer 14 typically has thickness between 0.1 nanometers to 0.1 millimeters and comprises the material that is known to assist the epitaxial layer 12 growth. In additional embodiments of the present invention, the seed layer can be further patterned, annealed or modified in any other way discovered by skilled artisan in order to improve the epitaxial layer 12 quality.

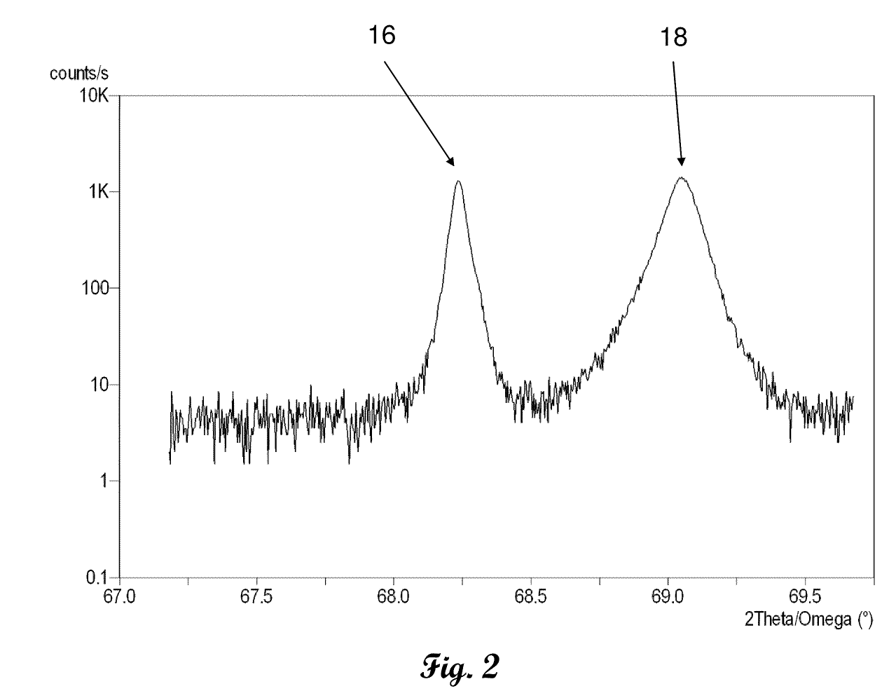

As an example of the structure of FIG. 1, the high quality Gallium Nitride layer was epitaxially grown in semi-polar direction over the m-plane sapphire substrate using the seed layer comprising Magnesium and Nitrogen. FIG. 2 presents the X-ray Diffraction (XRD) data in a form of 2Theta/Omega scan revealing two distinct peaks 16 and 18, the first 16 being typical for the sapphire m-plane (30-30), and the second 18 being typical for the semi-polar Gallium Nitride plane (11-22). The seed layer does not produce a distinct peak on the XRD data due to its extremely low thickness.

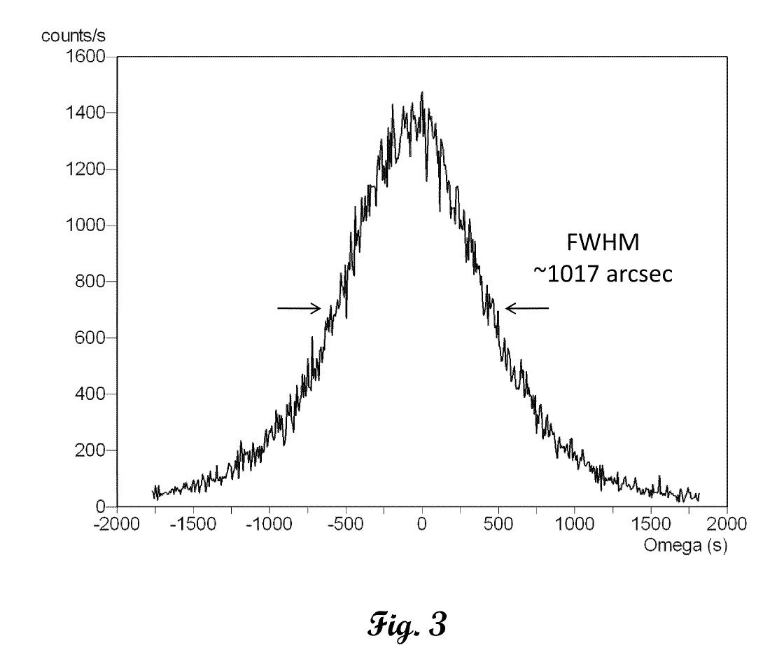

FIG. 3 presents the XRD data in a form of the Omega scan that is used to characterize the quality of the obtained epitaxial crystal layer. The Full Width at Half Maximum (FWHM) of the peak is 1017 arc-seconds, which makes the measured peak one of the sharpest (and thus the crystal quality one of the best) demonstrated for the semi-polar Gallium Nitride epitaxial films.

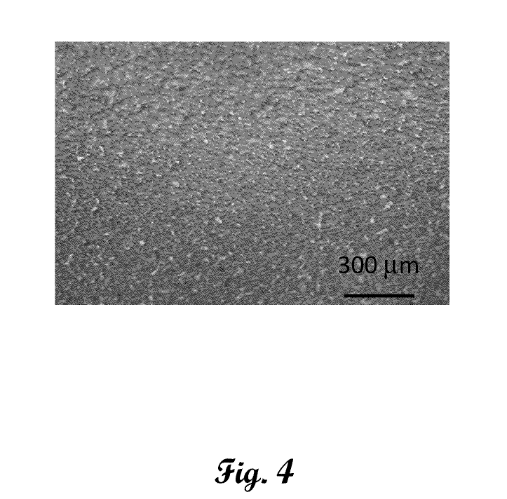

FIG. 4 shows the low-resolution DIC Microscopy image of the surface of semi-polar Gallium Nitride grown over the m-plane sapphire substrate by conventional method, without using the Magnesium-comprising seed layer. The granular structure of the surface clearly observed in the microphotograph corresponds to the polycrystalline nature of the obtained material, which is therefore hardly suitable for the majority of electronic and optoelectronic applications.

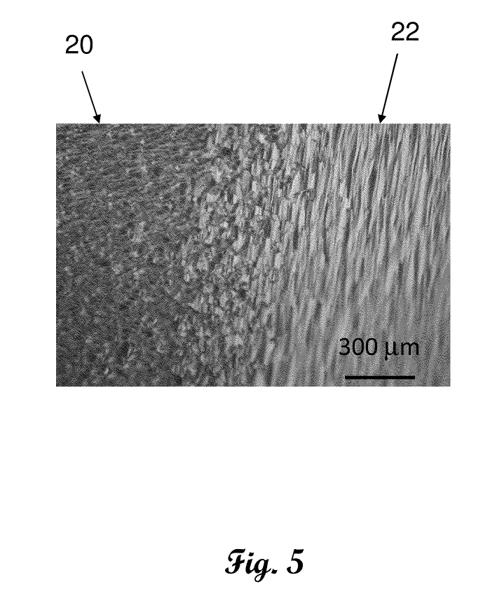

Another DIC Microscopy image of the surface of the said semi-polar Gallium Nitride film grown over the m-plane sapphire substrate by the conventional method, without using the Magnesium-comprising seed layer, is given in FIG. 5. The left hand side 20 of the microphotograph reveals the same granular structure as FIG. 4, while the right hand side 22 of FIG. 5 shows a smooth crystalline surface and corresponds to the region where a single crystal film was grown. This portion of the film is suitable for the device fabrication; however, due to low yield and unpredictability of the growth, it cannot be used for mass production of semiconductor devices.

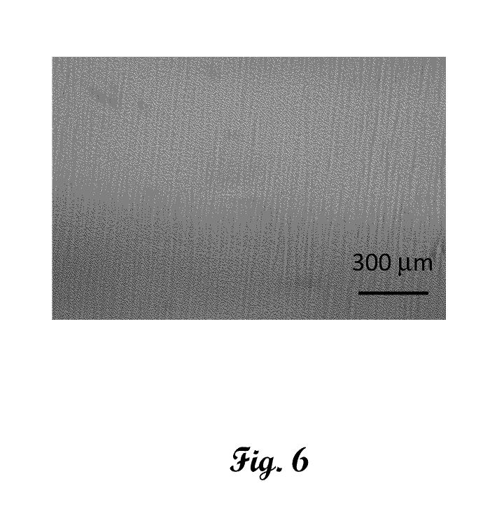

FIG. 6 shows the low-resolution DIC Microscopy image of the surface of semi-polar Gallium Nitride grown over the m-plane sapphire substrate by the method provided by present invention. From FIG. 6, a high quality, smooth-surface semiconductor film is obtained by epitaxial growth.

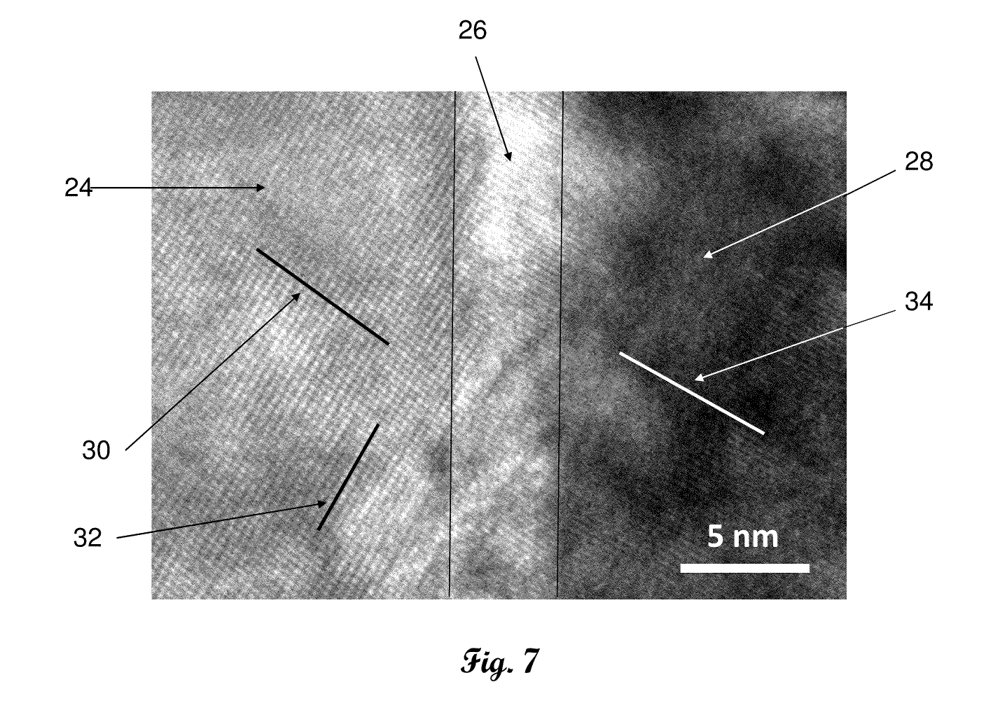

FIG. 7 presents the high-resolution Transmission Electron Microscopy (TEM) image of the substrate/epitaxial layer interface of the structure of FIG. 1. Crystallographic planes (1-104) 30 and (−1102) 32 are distinctly seen within the sapphire substrate 24 (the lines are guides to the eye). The crystallographic plane (0002) 34, or c-plane, is distinctly seen within the Gallium Nitride epitaxial layer 28 (the line is a guide to the eye). Between the substrate 24 and GaN film 28, the seed layer 26 with the crystallographic structure close to both structures of the substrate 28 and GaN film 28 is present. The thickness of the seed layer is around 4 nanometers. According to FIG. 7, good crystalline structure of grown GaN film is observed due to the presence of the seed layer that allows for good lattice matching between substrate 24 and GaN film 28.

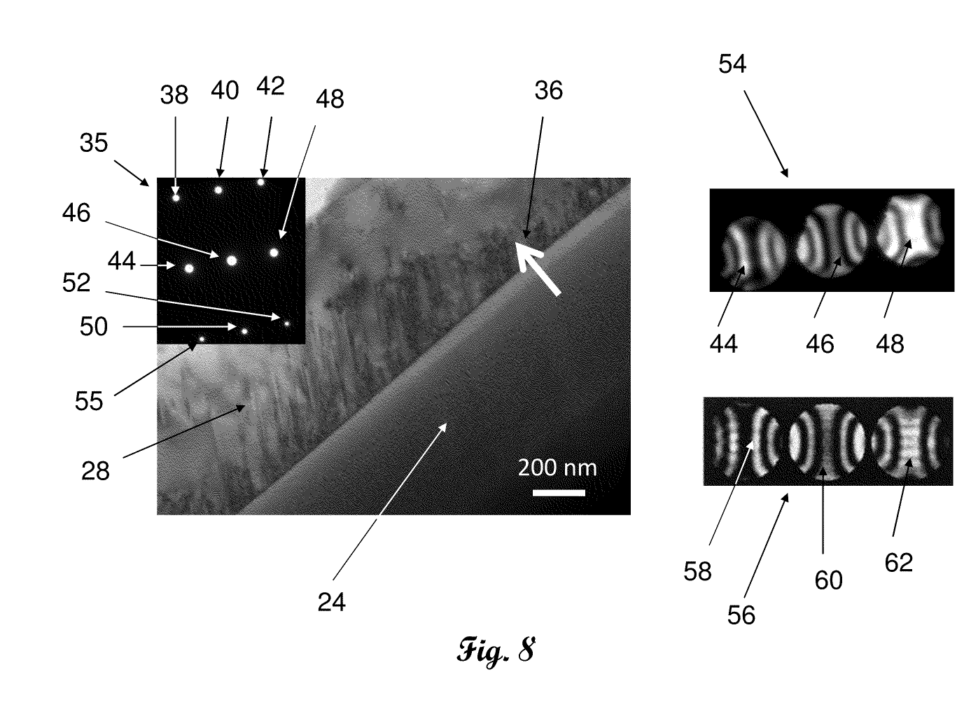

The data supporting the establishment of the face type of the film of FIGS. 6 and 7 is demonstrated in FIG. 8. The Electron Beam Diffraction pattern 35 of the GaN film 28 grown on the sapphire substrate 24 in the direction depicted by arrow 36 reveals the bright spots corresponding to the crystallographic planes (−1-120) 40, (0000) 46 and (11-20) 50, and crystallographic plane families with yet unspecified polarity (−1-122) or (−1-12-2) 38 and 42, (0002) or (000-2) 44 and 48, and (11-22) or (11-2-2) 52 and 55. The Convergent Beam Electron Diffraction (CBED) pattern 54 is taken for the spots 44, 46 and 48 of the Electron Beam Diffraction pattern 35. The said CBED pattern 54 is then compared to the simulated CBED pattern 56 of GaN at a thickness of 150 nm from (P. Ruterana, “Convergent beam electron diffraction investigation of inversion domains in GaN”, Journal of Alloys and Compounds, Volume 401, Issues 1-2, Pages 199-204, 2005). The internal structure of the simulated pattern 56 discs is known to correspond, from left to right, to [000-2] 58, [0000] 60 and [0002] 62 directions of the crystal lattice. Thus, the measured discs in the pattern 54 also correspond, from left to right, to [000-2] 44, [0000] 46 and [0002] 48 directions of the crystal lattice. From this, it is concluded that the positive direction of the c-axis in the GaN film 28 is pointing to the right, while the GaN film 28 growth direction is towards the upper left of the FIG. 8. This reveals the Nitrogen face of the grown film.

It is understood that although all but the first of the presented drawings are related to sapphire substrate and Gallium Nitride film growth, it is only exemplary to the presented invention which, in other aspects, uses different single crystal substrates for semi-polar or non-polar Nitride materials' epitaxial growth using MOVPE technique.

What is claimed is:

1. A method of epitaxial growth of a material, selected from the group of Boron Nitride, Aluminum Nitride, Gallium Nitride, Indium Nitride and their alloys, in the direction having at least one of the first three Miller-Bravais indices higher or equal to 1, the said method comprising the deposition step of a crystalline seed layer comprising Magnesium and Nitrogen.

2. A method of claim 1 where epitaxial growth is performed using the Metal-Organic Vapor Phase Epitaxy (MOVPE) technique.

3. A method of claim 2 where the said seed layer is deposited in-situ in the MOVPE reactor.

4. A method of claim 2 where the said seed layer is specially treated after deposition but prior to the Nitride material growth.

5. An epitaxial film of Boron-Aluminum-Gallium-Indium-Nitride grown using the method of any one of the claims 1-4.

6. A method of the substrate removal from the whole or a part of the epitaxial film of claim 5 by destroying the said seed layer.
